(19) United States
(12) Patent Application Publication
(10) Pub. No.: US 2026/0298974 A1
(43) Pub. Date: Oct. 1, 2026

(54) INSPECTION MEMBER

(71) Applicant: SAMSUNG ELECTRONICS CO., LTD., Suwon-si (KR)

(72) Inventors: Daisuke YAMADA, Yokohama (JP); Toshiki FURUTANI, Yokohama (JP); Takashi KARIYA, Yokohama (JP); Koji ASANO, Yokohama (JP)

(73) Assignee: SAMSUNG ELECTRONICS CO., LTD., Suwon-si (KR)

(21) Appl. No.: 19/629,824

(22) Filed: Mar. 26, 2026

(30) Foreign Application Priority Data
Mar. 27, 2025 (JP) 2025-054007

(51) Int. Cl. G01R 1/04

(52) U.S. Cl. CPC G01R 1/0433

(57) ABSTRACT

Provided is an inspection apparatus configured to test characteristics of an inspection target, the inspection apparatus including a contact layer configured to come into contact with an inspection point of the inspection target, a socket substrate on the contact layer opposite to the inspection target, and a conductive body connected to the socket substrate, opposite to the contact layer, the conductive body being connected to the inspection target through the socket substrate and the contact layer, wherein the contact layer includes a plurality of contact sections, each contact section of the plurality of contact sections includes a contact surface configured to contact the inspection point of the inspection target, the contact surface being configured to move in a first direction.

### CROSS-REFERENCE TO RELATED APPLICATION

This application claims priority to Japanese Patent Application No. 2025-054007, filed on Mar. 27, 2025, in the Japan Patent Office, the disclosure of which is incorporated herein in its entirety by reference.

### BACKGROUND

Embodiments of the present disclosure relate to an inspection apparatus.

An inspection jig head may inspect wiring patterns of each unit inspection substrate on a sheet substrate. The inspection jig head may include a plurality of inspection probes, each coming into contact with an inspection point on a wiring pattern formed on a unit inspection substrate to inspect the wiring pattern.

### SUMMARY

According to an aspect of one or more embodiments, there is provided an inspection apparatus configured to test characteristics of an inspection target, the inspection apparatus including a contact layer configured to come into contact with an inspection point of the inspection target, a socket substrate on the contact layer opposite to the inspection target, and a conductive body connected to the socket substrate, opposite to the contact layer, the conductive body being connected to the inspection target through the socket substrate and the contact layer, wherein the contact layer includes a plurality of contact sections, each contact section of the plurality of contact sections includes a contact surface configured to contact the inspection point of the inspection target, the contact surface being configured to move in a first direction.

According to another aspect of one or more embodiments, there is provided an inspection apparatus configured to test characteristics of an inspection target, the inspection apparatus including a contact layer configured to contact an inspection point of the inspection target, a socket substrate on the contact layer opposite to the inspection target, and a conductive body connected to the socket substrate opposite side to contact layer, the conductive body being configured to be connected to the inspection target through the socket substrate and the contact layer, wherein the contact layer includes a plurality of contact sections separated from each other in a horizontal direction, and wherein each contact section of the plurality of contact sections is configured to move such that an upper surface of each contact section of the plurality of contact sections is inclined relative to a reference plane.

According to still another aspect of one or more embodiments, there is provided an inspection apparatus configured to test characteristics of an inspection target, the inspection apparatus including a contact layer configured to contact an inspection point of the inspection target, a socket substrate on the contact layer opposite to the inspection target, and a conductive body connected to the socket substrate opposite to the contact layer, the conductive body being configured to be connected to the inspection target through the socket substrate and the contact layer, wherein the socket substrate includes a plurality of socket sections separated from each other in a horizontal direction, wherein the contact layer includes a plurality of contact sections on an upper surface of each socket section of the plurality of socket sections, and wherein a durometer hardness of the socket substrate is greater than a durometer hardness of the contact layer.

### BRIEF DESCRIPTION OF DRAWINGS

Embodiments will be more clearly understood from the following detailed description taken in conjunction with the accompanying drawings in which:

FIG. 1 is a view illustrating an example of a configuration of an inspection device according to one or more embodiments;

FIG. 2 is an enlarged view of a portion II in FIG. 1;

FIG. 3 is a view illustrating an example of a configuration of a semiconductor package to be inspected by an inspection device according to one or more embodiments;

FIG. 4 is a view of a contact sheet and a socket substrate as viewed in the z direction according to one or more embodiments;

FIGS. 5A and 5B are views illustrating examples of a relationship between a semiconductor package and a contact layer when warpage occurs in the semiconductor package;

FIG. 6 is a view illustrating an example of a state in which a warped semiconductor package is mounted on an inspection jig head;

FIG. 7 is a view illustrating a configuration of an inspection device according to one or more other embodiments; and

FIG. 8 is a view illustrating a contact sheet and a socket substrate as viewed in the z direction according to one or more other embodiments.

### DETAILED DESCRIPTION

Hereinafter, embodiments of the disclosure will be described with reference to the accompanying drawings. Also, the disclosure is not limited to the embodiments described below. Also, the disclosure may be implemented with various modifications within the scope of the disclosure. Furthermore, the drawings used below are for the purpose of describing embodiments of the disclosure and are not necessarily to actual size.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c. Also, the term “and/or” includes any and all combinations of one or more of the associated listed items. For example, an expression, “a and/or b” should be understood as including only a, only b and both a and b.

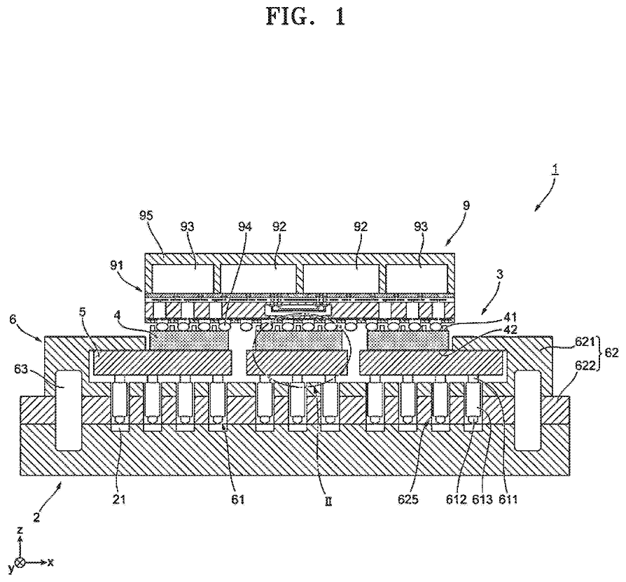

FIG. 1 is a view illustrating an example of a configuration of an inspection device according to one or more embodiments. In FIG. 1, a direction extending from left to right is referred to as an x-direction, a direction extending inward from the front is referred to as a y direction, and a direction extending upward from the bottom is referred to as a z direction. The z direction is an example of a stack direction. FIG. 1 corresponds to a cross-sectional view of the inspection device 1, which is taken along the x direction and z direction.

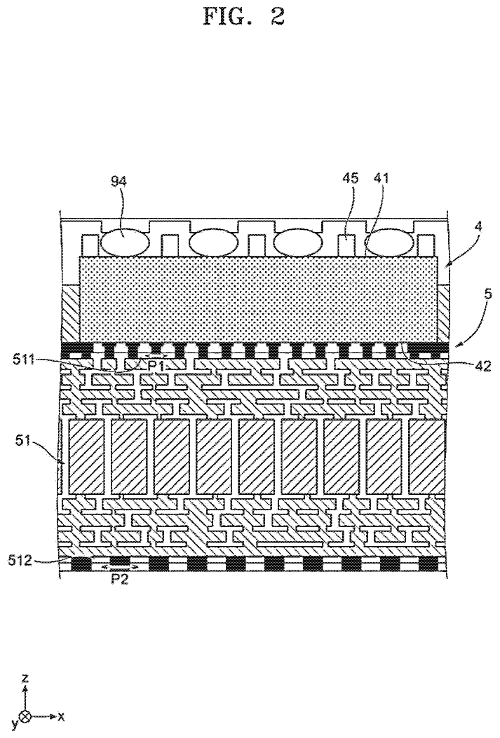

FIG. 2 is an enlarged view of a portion II in FIG. 1.

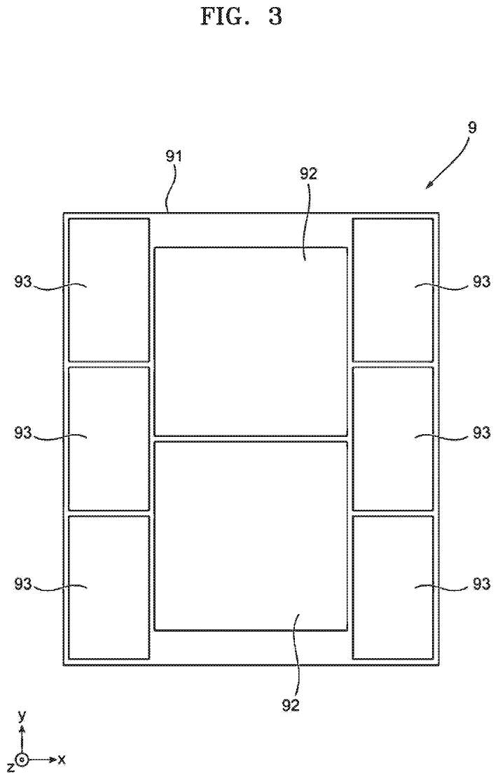

FIG. 3 is a view illustrating an example of a configuration of a semiconductor package 9 to be inspected by the inspection device 1. FIG. 3 corresponds to a view of the semiconductor package 9, as viewed from the z direction. Also, a mold 95 of the semiconductor package 9, which is described below, is omitted in FIG. 2.

The semiconductor package 9 to be inspected by the inspection device 1 is described. The semiconductor package 9 is an example of an inspection target.

The semiconductor package 9 includes an interposer substrate 91. Also, the semiconductor package 9 includes a plurality of logic devices 92 installed on an upper surface of the interposer substrate 91. For example, the semiconductor package 9 may include two logic devices 92. Also, the semiconductor package 9 includes a plurality of memory devices 93 installed on the upper surface of the interposer substrate 91. For example, the semiconductor package 9 may include six memory devices 93. Also, the semiconductor package 9 includes a plurality of connection terminals 94 installed on a lower surface of the interposer substrate 91. Also, the semiconductor package 9 includes the mold 95 that covers and/or is provided on the plurality of logic devices 92 and the plurality of memory devices 93.

The interposer substrate 91 includes a redistribution layer that electrically connects the plurality of logic devices 92 and the plurality of memory devices 93 to the plurality of connection terminals 94. Also, the interposer substrate 91 may include, for example, at least one capacitor, at least one an inductor, etc.

The plurality of logic devices 92 may each be a semiconductor device including a logic circuit configured in a semiconductor layer. The plurality of logic devices 92 may each include, for example, a central processing unit (CPU), a graphics processing unit (GPU), an application specific integrated circuit (ASIC), and so on.

The plurality of memory devices 93 may each be a semiconductor device including a memory circuit configured in a semiconductor layer. The plurality of memory devices 93 may each include dynamic random access memory (DRAM), static random access memory (SRAM), ferroelectric random access memory (FeRAM), flash memory, and so on. Also, the plurality of memory devices 93 may each be a high bandwidth memory (HBM) in which a plurality of DRAMs are stacked in the z direction.

The plurality of connection terminals 94 may be used to mount the semiconductor package 9 on a package substrate of a semiconductor device, an inspection jig head 3 of an inspection device 1, etc. When the semiconductor package 9 mounted on the interposer substrate 91 is mounted on the inspection jig head 3 of the inspection device 1, the plurality of connection terminals 94 may each be used as an inspection point.

The plurality of connection terminals 94 may each include a conductive material. For example, the conductive material constituting each of the plurality of connection terminals 94 may include a metal, such as, for example, copper, aluminum, silver, tin, gold, titanium, nickel, tungsten, and an alloy thereof. The plurality of connection terminals 94 may each be, for example, a solder ball.

Also, although the semiconductor package 9 including the plurality of logic devices 92 and the plurality of memory devices 93 mounted on the interposer substrate 91 is used as an inspection target of the inspection device 1 in the embodiment, a configuration of the semiconductor package 9 is not limited thereto.

Also, the inspection target of the inspection device 1 may be another device other than the semiconductor package 9. For example, the inspection target of the inspection device 1 may be a semiconductor device or a semiconductor module stacked on another substrate, such as a package substrate, in addition to the semiconductor package 9. Also, the inspection target of the inspection device 1 may be a semiconductor substrate that does not include the plurality of logic devices 92, the plurality of memory devices 93, etc.

Next, a configuration of the inspection device 1 will be described.

The inspection device 1 test electrical characteristics of the semiconductor package 9 by being electrically connected to the semiconductor package 9. For example, testing the electrical characteristics of the semiconductor package 9 by using the inspection device 1 may include a test for a resistance value, a short circuit, a disconnected wire, and so on of the semiconductor package 9.

The inspection device 1 includes a test board 2. Also, the inspection device 1 includes the inspection jig head 3 that supports the semiconductor package 9 and electrically connects the semiconductor package 9 to the test board 2. Also, the inspection device 1 may include a pressing device that presses the semiconductor package 9 against the inspection jig head 3.

The test board 2 may be connected to a control device and performs an operation related to inspection of the semiconductor package 9 based on the control by the control device. Additionally, the test board 2 outputs an electrical signal for inspection to the semiconductor package 9 through the inspection jig head 3. Also, the test board 2 receives an electrical signal representing an inspection result output from the semiconductor package 9. The control device determines whether the semiconductor package 9 is good or bad based on an electrical signal received by the test board 2 and outputs the inspection result.

The test board 2 is configured with, for example, a semiconductor substrate including a chip, a circuit, terminals, and so on necessary for inspection of the semiconductor package 9.

Also, the test board 2 includes a plurality of pads 21 which are on a surface facing the inspection jig head 3 and come into contact with a plurality of probes 61 of the inspection jig head 3 described below to be electrically connected to the probes 61. The test board 2 inputs and receives electrical signals to and from the inspection jig head 3 and the semiconductor package 9 through the plurality of pads 21.

When an inspection of the semiconductor package 9 (see FIG. 1) is performed by the inspection device 1, the semiconductor package 9 is mounted on the inspection jig head 3 and is electrically connected to the test board 2. The inspection jig head 3 is an example of an inspection apparatus.

The inspection jig head 3 includes a contact sheet 4 that comes into contact with the plurality of connection terminals 94 of the semiconductor package 9. Also, the inspection jig head 3 includes a socket substrate 5 stacked on an opposite side to the contact sheet 4 from the semiconductor package 9. Also, the inspection jig head 3 includes a conductive body 6 that is installed on an opposite side to the socket substrate 5 from the contact sheet 4 and electrically connects the test board 2 to the socket substrate 5. Herein, the contact sheet 4 may be an example of a contact layer or may be included in the example of the contact layer.

The contact sheet 4 has a sheet-like shape extending in the x direction and the y direction. Additionally, the contact sheet 4 has an upper surface 41 facing the semiconductor package 9 mounted on the inspection jig head 3 and a lower surface 42 in contact with the socket substrate 5.

Also, a plurality of guides 45 are provided on the upper surface 41 of the contact sheet 4 to guide positions where the plurality of connection terminals 94 come into contact with the contact sheet 4 when the semiconductor package 9 is mounted on the inspection jig head 3. The plurality of guides 45 may each be formed of an insulating material. Additionally, when the semiconductor package 9 is mounted on the inspection jig head 3, the semiconductor package 9 is stacked on the contact sheet 4 such that the plurality of connection terminals 94 are alternately inserted between the plurality of guides 45.

The contact sheet 4 may have elasticity. The fact that the contact sheet 4 has elasticity indicates that, when the semiconductor package 9 is mounted on the inspection jig head 3, the upper surface 41, which is a contact surface coming into contact with the plurality of connection terminals 94 may be deformed because the plurality of connection terminals 94 are pressed onto the contact sheet 4 to be in close contact therewith. The contact surface of the contact sheet 4 may be moved in a stack direction (for example, the z direction).

Because the contact sheet 4 is elastic, damage, which is caused when the plurality of connection terminals 94 come into contact with the contact sheet 4 during mounting of the semiconductor package 9 on the inspection jig head 3, may be reduced.

A tensile strength of the contact sheet 4 may be, for example, in the range of 10 kg/cm² to 500 kg/cm² and may be in the range of 30 kg/cm² to 200 kg/cm².

Also, a durometer hardness of the contact sheet 4 may be, for example, in the range of 10 to 100 in type A. As described below, a durometer hardness of the contact sheet 4 is lower than a durometer hardness of the socket substrate 5.

A thickness of the contact sheet 4 is preferably 5 μm to 1,000 μm, and may be 20 μm to 500 μm.

When the thickness of the contact sheet 4 is less than 5 μm, damage to the connection terminal 94 when coming into contact with the contact sheet 4 may not be sufficiently reduced. When the thickness of the contact sheet 4 exceeds 1,000 μm, electrical resistance between the semiconductor package 9 and the socket substrate 5 may increase. Also, when the thickness of the contact sheet 4 exceeds 1,000 μm, the inspection jig head 3 may be enlarged in the z direction.

Also, the contact sheet 4 has anisotropic conductivity. The anisotropic conductivity indicates that the contact sheet 4 is conductive in the z direction that is a thickness direction of the contact sheet 4 and is insulated in the x direction and y direction which are plane directions of the contact sheet 4.

The contact sheet 4 includes an insulating elastomer and a conductor. Additionally, the contact sheet 4 has a configuration in which a conductor is formed or filled inside the insulating elastomer. For example, the contact sheet 4 may have a configuration including an insulating elastomer having a plurality of through-holes penetrating the insulating elastomer in the z direction and conductors respectively installed inside the plurality of through-holes.

The insulating elastomer may be a thermosetting elastomer, a thermoplastic elastomer, etc.

The thermosetting elastomer may include, for example, urethane rubber, isoprene rubber, ethylene propylene rubber, styrene butadiene rubber, natural rubber, fluororubber, silicone rubber, etc.

The thermoplastic elastomer may include, for example, a urethane-based thermoplastic elastomer, an ester-based thermoplastic elastomer, a styrene-based thermoplastic elastomer, an olefin-based thermoplastic elastomer, a butadiene-based thermoplastic elastomer, a fluorine-based thermoplastic elastomer, etc.

The elastomers may use one of the materials or a combination thereof.

The conductor may include a metal-based conductor, a metal oxide-based conductor, a carbon-based conductor, etc.

The metal-based conductor may include, for example, a metal, such as copper, silver, gold, aluminum, iron, nickel, zinc, and titanium, or an alloy thereof.

The metal oxide-based conductor may include, for example, tin oxide, indium oxide, zinc oxide, indium tin oxide (ITO), indium zinc oxide (IZO), etc.

The carbon-based conductor may include, for example, carbon black, graphite, etc.

The conductors may each use one of the materials or a combination of two or more materials.

Also, a shape of the conductor is not limited in particular and may include, for example, a thin-film shape, a particle shape, a wire shape, a fiber shape, a plate shape, a flake shape, etc.

The inspection jig head 3 according to the embodiment may reduce inductance between the semiconductor package 9 and the test board 2 by using the contact sheet 4 for connection to the semiconductor package 9. Accordingly, the inspection device 1 may achieve high-frequency performance and increase accuracy of the inspection on the semiconductor package 9 which is performed by the inspection device 1.

The contact sheet 4 according to one or more embodiments is divided into a plurality of sections by being cut along the x direction and the y direction. Additionally, the contact sheet 4 includes a plurality of sections arranged in the x direction and the y direction, which are plane directions of the contact sheet 4. The plurality of sections may be referred to as a plurality of contact sections. For example, the contact sheet 4 may include a plurality of contact sections. The plurality of contact sections may be separated and/or spaced apart from each other in a horizontal direction (for example, the x direction and/or the y direction). Each of the plurality of contact sections may be movable such that the plurality of contact sections (for example, upper surfaces of the plurality of contact sections) are inclined relative to a reference plane. For example, as an inspection target comes into contact with a contact layer, each of the plurality of contact sections may be moved to have a different inclination relative to the reference plane. In one or more embodiments, the reference plane may be a lower surface of the conductive body 6. Each of the plurality of contact sections may be moved in a vertical direction (the z direction).

In addition, respective sections of the contact sheet 4 are deformed individually and elastically by pressing the plurality of connection terminals 94 onto the contact sheet 4 to be in closer contact therewith when the semiconductor package 9 is mounted on the inspection jig head 3.

Also, a shape and function of the contact sheet 4 will be described below in more detail.

The socket substrate 5 is a printed wiring substrate including a wire 51, which is formed on a surface of the substrate and inside the substrate, for transmitting electrical signals. Also, the socket substrate 5 is a rigid board with no flexibility and relatively high rigidity.

The socket substrate 5 may be sufficiently rigid compared to the contact sheet 4. A durometer hardness of the socket substrate 5 may be, for example, 90 or more in type A, and may be, for example, 200 or more.

The socket substrate 5 has a greater durometer hardness than a durometer hardness of the contact sheet 4, and accordingly, the socket substrate 5 may be more stably connected to the probes 61 (described below) of the conductive body 6.

The wire 51 of the socket substrate 5 includes a first wire 511 that comes into contact with the contact sheet 4 and a second wire 512 that comes into contact with the probe 61 of the conductive body 6.

For example, in the wire 51 of the socket substrate 5 that a pitch P1 of the first wire 511 is less than a pitch P2 of the second wire 512. In one or more embodiments, the pitch P1 of the first wire 511 refers to a value obtained by adding a line width of one of periodically arranged first wires 511 to an interval between adjacent first wires 511. When line widths or intervals of a plurality of first wires 511 are different from each other, an average value of the line width of the first wire 511 plus the interval between adjacent first wires 511 is used as the pitch P1 of the first wire 511. The same applies to the pitch P2 of the second wire 512.

The pitch P1 of the first wire 511 may be in the range of 5 μm to 200 μm.

Also, the pitch P2 of the second wire 512 may be in the range of 200 μm to 3000 μm.

Because the pitch P2 of the second wire 512 is 200 μm or more, a probe may be used as the probe 61.

The socket substrate 5 according to one or more embodiments is divided into a plurality of sections by being cut along the x direction and the y direction, similar to the contact sheet 4. For example, the socket substrate 5 includes a plurality of sections arranged in the x direction and the y direction, which are plane directions of the socket substrate 5. The sections may be referred to as a plurality of socket sections. For example, the socket substrate 5 may include a plurality of socket sections. The plurality of socket sections may be separated and/or spaced apart from each other in a horizontal direction (for example, the x direction and/or the y direction). Each of the plurality of socket sections may be movable such that the plurality of socket sections (for example, upper surfaces of the plurality of socket sections) are inclined relative to a reference plane. For example, as an inspection target comes into contact with a contact layer, each of the plurality of socket sections may be moved to have a different inclination relative to the reference plane. Each of the plurality of contact layers may be arranged on an upper surface of each of the plurality of socket sections. In one or more embodiments, the reference plane may be a lower surface of the conductive body 6. Each of the plurality of socket sections may be movable in a vertical direction (the z direction).

In addition, when the semiconductor package 9 is mounted on the inspection jig head 3, respective sections of the socket substrate 5 may be individually moved in a vertical direction (the z direction), together with the contact sheet 4 stacked on the socket substrate 5.

A shape and function of the socket substrate 5 will be described below in more detail.

The conductive body 6 is installed on an opposite side to the socket substrate 5 from the contact sheet 4. In one or more embodiments, a part of the conductive body 6 may be on a side surface and/or upper surface of the contact sheet 4. The conductive body 6 electrically connects the test board 2 to the socket substrate 5.

The conductive body 6 electrically connects the test board 2 to the socket substrate 5 and includes the plurality of probes 61 that transmit electrical signals between the test board 2 and the socket substrate 5. Also, the conductive body 6 includes a probe holder 62 that supports the plurality of probes 61. Furthermore, the conductive body 6 includes a connection member 63 that connects the probe holder 62 to the test board 2.

The probe holder 62 includes a first holder 621 and a second holder 622 that are stacked in the z direction. The first holder 621 and the second holder 622 may each be formed of an insulating material.

The first holder 621 is installed on an upper side in the z direction and faces the socket substrate 5. Also, the first holder 621 supports the probe 61 and movably supports the contact sheet 4 and the socket substrate 5 in the z direction.

The second holder 622 is installed on a lower side in the z direction and is stacked on an upper surface of the test board 2.

The probe holder 62 has a plurality of through-holes 625 into which the plurality of probes 61 are respectively inserted. Each of the plurality of through-holes 625 is a cylindrical space that penetrates the first holder 621 and the second holder 622 in the z direction.

Each of the plurality of through-holes 625 is formed at a position facing the second wire 512 formed on the socket substrate 5 and a pad 21 formed on an upper surface of the test board 2.

The probe 61 includes a first plunger 611 that comes into contact with the socket substrate 5 and a second plunger 612 that comes into contact with the pad 21 of the test board 2. Also, the probe 61 includes a cylindrical barrel 613 that accommodates the first plunger 611 and the second plunger 612. Also, the probe 61 may include a spring that is accommodated in the barrel 613 and is flexibly connects the first plunger 611 to the second plunger 612 in the z direction. The first plunger 611, the second plunger 612, the barrel 613, and the spring that constitute the probe 61 are formed of a conductive material.

The probe 61 is supported by the probe holder 62 by being inserted into the through-hole 625 formed in the probe holder 62.

As described above, the through-hole 625 of the probe holder 62 is formed at a position facing the second wire 512 formed in the socket substrate 5. Accordingly, an interval between adjacent probes 61 is equal to the pitch P2 of the second wire 512 on the socket substrate 5. Additionally, the interval between adjacent probes 61 may be in the range of 200 μm to 3000 μm, similar to the pitch P2 of the second wire 512.

The first plunger 611 is pressed in the z direction by an elastic force of the spring and comes into contact with the socket substrate 5. For example, the first plunger 611 comes into contact with the second wire 512 formed on the socket substrate 5. Accordingly, the probe 61 is electrically connected to the wire 51 of the socket substrate 5.

The second plunger 612 is pressed in the z direction by the elastic force of the spring and comes into contact with the pad 21 of the test board 2. Accordingly, the probe 61 is electrically connected to the test board 2.

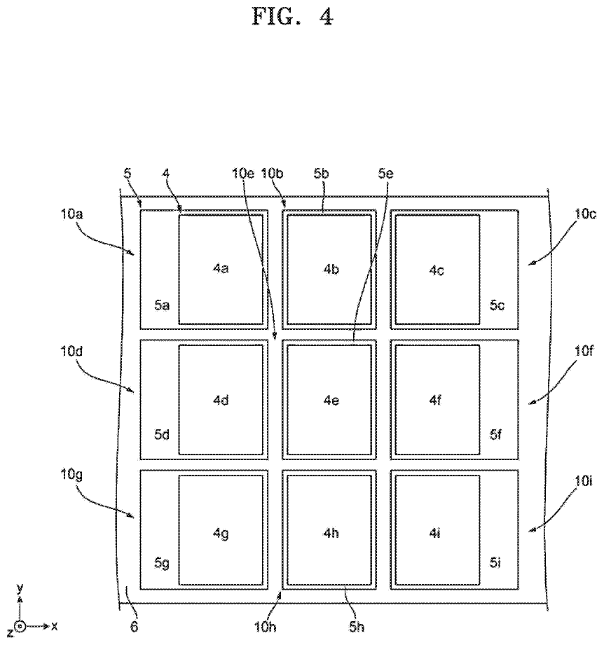

FIG. 4 is a view of the contact sheet 4 and the socket substrate 5 as viewed in the z direction according to one or more embodiments.

Shapes of the contact sheet 4 and the socket substrate 5 of the inspection jig head 3 will be described in more detail with reference to FIG. 1 and FIG. 4.

As described above, the contact sheet 4 and the socket substrate 5 according to one or more embodiments are divided into a plurality of sections arranged in the x direction and the y direction by being cut along the x direction and the y direction.

For example, the contact sheet 4 is divided into nine contact sections 4a, 4b, . . . , 4i in which three contact sections are arranged in the x direction and three contact sections are arranged in the y direction. The nine contact sections 4a to 4i of the contact sheet 4 are an example of a plurality of contact sections. Each of a plurality of contact sections 4a to 4i includes an upper surface 41 (see FIG. 2), which is a contact surface with which the connection terminal 94 comes into contact.

The socket substrate 5 is divided into nine sections 5a, 5b, . . . , 5i in which three sections are arranged in the x direction and three sections are arranged in the y direction. The nine sections 5a to 5i of the socket substrate 5 are an example of a plurality of socket sections. Here, each of the plurality of contact sections 4a to 4i of the contact sheet 4 is stacked on each of a plurality of socket sections 5a to 5i of the socket substrate 5 to which the same alphabets a to i are assigned.

In the following description, a portion where the contact section 4a of the contact sheet 4 is stacked on the section 5a of the socket substrate 5 may be referred to as a stacked body 10a using a corresponding alphabet. The same applies to portions where the contact sections 4b to 4i of the contact sheet 4 are stacked on the sections 5b to 5i of the socket substrate 5. For example, the contact sheet 4 and the socket substrate 5 according one or more embodiments are divided into nine stacked bodies 10a to 10i in which three sections are arranged in the x direction and three sections are arranged in the y direction.

In addition, when the semiconductor package 9 is mounted on the inspection jig head 3, the stacked bodies 10a to 10i may be individually moved in the z direction according to a pressing force exerted by the semiconductor package 9 on the contact sections 4a to 4i of the contact sheet 4. Accordingly, the upper surface 41 (see FIG. 2) of the contact sheet 4, which is a contact surface with which the plurality of connection terminals 94 come into contact, may be individually moved in the z direction for each of the contact sections 4a to 4i.

In this example, when the semiconductor package 9 is mounted on the inspection jig head 3, the stacked bodies 10a, 10c, 10d, 10f, 10g, and 10i are arranged at positions facing 1:1 to the plurality of memory devices 93 of the semiconductor package 9.

Also, when the semiconductor package 9 is mounted on the inspection jig head 3, the stacked bodies 10b, 10e, and 10h are arranged at positions facing the plurality of logic devices 92 of the semiconductor package 9.

However, warpage may occur in the semiconductor package 9, which is an inspection target of the inspection device 1, due to a stack structure of the semiconductor package 9 or materials of respective layers constituting the semiconductor package 9. In addition, when warpage occurs in the semiconductor package 9, problems, such as poor contact between a contact layer electrically connected to the semiconductor package 9 and the connection terminal 94 of the semiconductor package 9, may arise when the semiconductor package 9 is mounted on the inspection jig head 3.

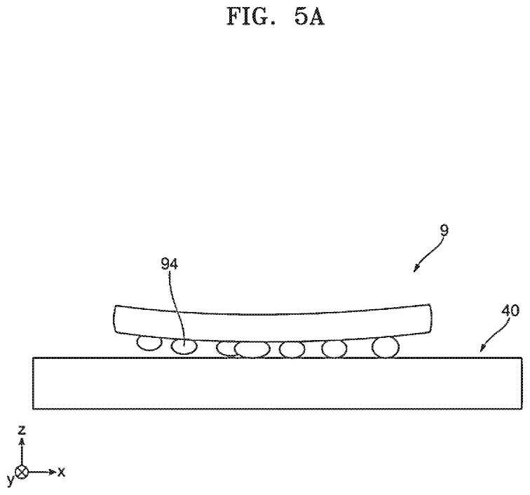

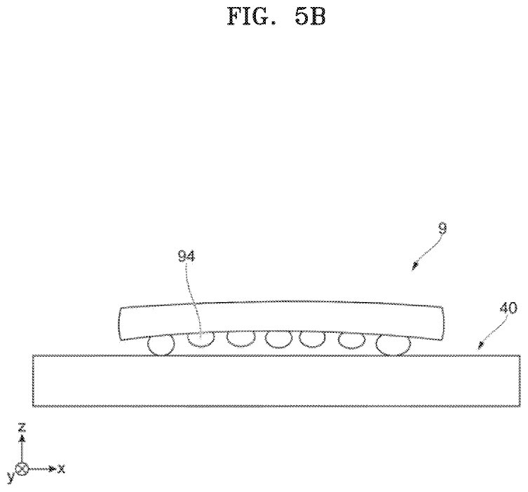

FIGS. 5A and 5B are views illustrating examples of a relationship between the semiconductor package 9 and a contact layer 40 when warpage occurs in the semiconductor package 9.

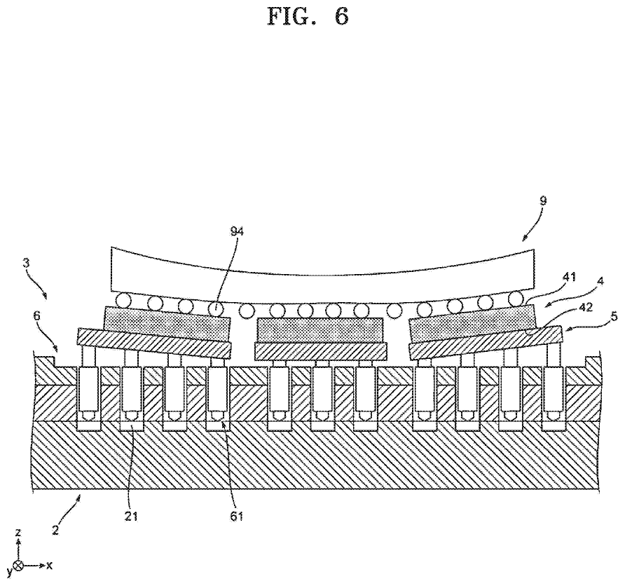

Also, in the descriptions of FIGS. 5A and 5B, the same reference numerals are used for the same components as in the embodiment described above. Also, detailed descriptions of the semiconductor package 9 are omitted in FIGS. 5A, 5B, and 6, except for the plurality of connection terminals 94.

The contact layer 40 corresponds to the contact sheet 4 (see FIG. 1) and the socket substrate 5 (see FIG. 1) of the inspection jig head 3 (see FIG. 1) according to the embodiment. Additionally, the contact layer 40 is a member that transmits an electrical signal between the semiconductor package 9 and the conductive body 6 (see FIG. 1).

The contact layer 40 is, for example, a printed wiring board including wires for transmitting electric signals, the wires formed on a surface and in the inside of the printed wiring board.

As another example, the contact layer 40 is formed as a single unit without being divided into a plurality of sections.

When warpage occurs in the semiconductor package 9, a distance between the contact layer 40 and the connection terminal 94 at the end of the semiconductor package 9 is different from a distance between the contact layer 40 and the connection terminal 94 at the center of the semiconductor package 9. Due to this, in a region where a distance between the contact layer 40 and the connection terminal 94 is longer, poor contact may occur between the connection terminal 94 and the contact layer 40. Also, in a region where the distance between the contact layer 40 and the connection terminal 94 is shorter, a pressing force of the connection terminal 94 against the contact layer 40 may increase, resulting in damage to the connection terminal 94, or adjacent connection terminals 94 may come into contact with each other, resulting in a short circuit in wires.

For example, when warpage, such as downward convexity in the z direction occurs in the semiconductor package 9 as illustrated in FIG. 5A, poor contact may occur at the end of the semiconductor package 9, and damage to the connection terminal 94 or a short circuit in wires may occur in a central portion of the semiconductor package 9.

Also, when warpage, such as upward convexity in the z direction, occurs in the semiconductor package 9 as illustrated in FIG. 5B, poor contact may occur in the central portion of the semiconductor package 9, and damage to the connection terminal 94 or a short circuit in wires may occur at end portions of the semiconductor package 9.

In this regard, in the inspection jig head 3 according to one or more embodiments, the contact sheet 4 is divided into a plurality of contact sections 4a to 4i, and the socket substrate 5 is divided into a plurality of socket sections 5a to 5i as described above. In addition, the upper surfaces 41 of the contact sheet 4, which come into contact with the plurality of connection terminals 94, may be individually moved in the z direction for each of the plurality of contact sections 4a to 4i.

Accordingly, in a state where the semiconductor package 9 is mounted on the inspection jig head 3, even when warpage occurs in the semiconductor package 9, it is possible to prevent poor contact between the connection terminal 94 and the contact sheet 4 from occurring.

Subsequently, an operation of the inspection jig head 3 on which the semiconductor package 9 is mounted will be described in detail, focusing on operations of the contact sheet 4 and the socket substrate 5.

FIG. 6 is a view illustrating an example of a state in which a warped semiconductor package 9 is mounted on the inspection jig head 3. In FIG. 6, a detailed configuration of the semiconductor package 9 except the connection terminal 94 is omitted.

Hereinafter, a case in which warpage, such as downward convexity in the z direction, occurs in the semiconductor package 9 will be described as an example.

When the semiconductor package 9 is inspected by the inspection device 1 (see FIG. 1), the semiconductor package 9 is placed on the contact sheet 4 of the inspection jig head 3. Then, the semiconductor package 9 is pressed in the z direction by a pressing device such that the plurality of connection terminals 94 of the semiconductor package 9 come into contact with the upper surface 41 of the contact sheet 4.

The pressing device may use a mechanical pressing method of pressing the semiconductor package 9 by using a pressure cylinder, a motor, etc. Also, the pressing device may use various pressing methods, such as an atmospheric pressing method of pressing the semiconductor package 9 in a state where the inspection jig head 3 and the semiconductor package 9 are in a vacuum. Also, the pressing device is not limited in particular as long as the semiconductor package 9 may be pressed against the contact sheet 4, and various pressing methods may be used for the pressing device. Additionally, because the inspection jig head 3 according to one or more embodiments may reduce damage to the plurality of connection terminals 94 as described below when the semiconductor package 9 is mounted on the inspection jig head 3, various pressing methods may be used without limitation.

When warpage occurs in the semiconductor package 9, a pressing force, by which the plurality of connection terminals 94 press the upper surface 41 of the contact sheet 4, changes depending on positions in the semiconductor package 9. In the example illustrated in FIG. 6, the pressing force of the plurality of connection terminals 94 pressing the upper surface 41 of the contact sheet 4 is less at the ends of the semiconductor package 9, in which distances between the inspection jig head 3 and the plurality of connection terminals 94 are longer, than at a central portion of the semiconductor package 9.

In the inspection jig head 3 according to one or more embodiments, the upper surfaces 41 of respective sections of the contact sheet 4 with which the plurality of connection terminals 94 come into contact move individually in the z direction according to the pressing force exerted by the plurality of connection terminals 94. For example, in the inspection jig head 3, respective sections of the contact sheet 4 are deformed individually and elastically depending on pressing forces exerted by the plurality of connection terminals 94. Also, in the inspection jig head 3, the plurality of probes 61 of the conductive body 6 expand and contract in the z direction depending on the pressing forces exerted by the plurality of connection terminals 94, such that respective sections of the contact sheet 4 and the socket substrate 5 move individually in the z direction.

Accordingly, even when a warped semiconductor package 9 is mounted on the inspection jig head 3, the plurality of connection terminals 94 come into contact more easily with respective sections of the contact sheet 4 by an appropriate pressing force. As a result, it is difficult for connection failures of the plurality of connection terminals 94 to the contact sheet 4, damage to the plurality of connection terminals 94 due to an increase in a pressing force against the contact sheet 4, or a short circuit in wires to occur.

Also, by preventing the connection failures of the plurality of connection terminals 94 to the contact sheet 4, the damage to the plurality of connection terminals 94, and a short circuit in wires, accuracy of the inspection on the semiconductor package 9 by the inspection device 1 (see FIG. 1) may be increased. As a result, a yield of the semiconductor package 9 itself and products using the semiconductor package 9 may be increased.

When warpage occurs in the entire semiconductor package 9, warpage may also occur in each region of the semiconductor package 9 facing each section of the contact sheet 4. However, a magnitude of the warpage occurring in each region of the semiconductor package 9 is less than a magnitude of the warpage in the entire semiconductor package 9.

In one or more embodiments, the contact sheet 4 may be elastic. Accordingly, even when warpage occurs in each region of the semiconductor package 9, each section of the contact sheet 4 may be elastically deformed, and accordingly, the influence of a difference between pressing forces of the plurality of connection terminals 94 depending on warpages may be reduced.

One or more other embodiments of the disclosure will be described. Also, the same reference numerals are used for the same components as embodiments described above, and detailed descriptions thereof are omitted below.

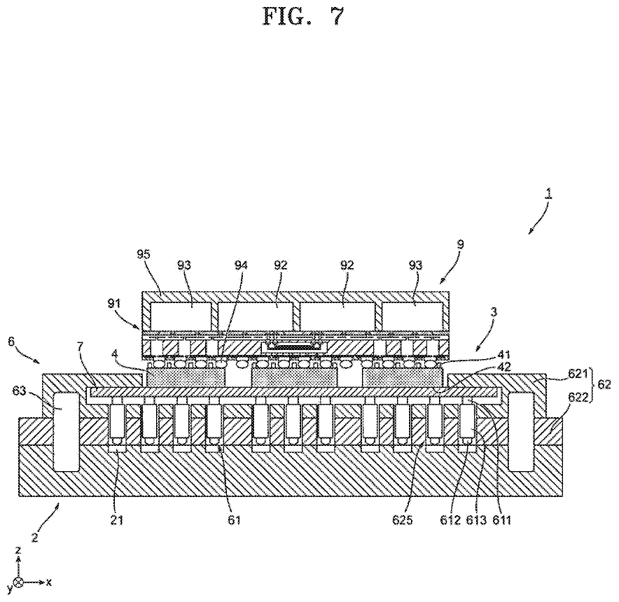

FIG. 7 is a view illustrating an example of a configuration of an inspection device 1 according to one or more other embodiments.

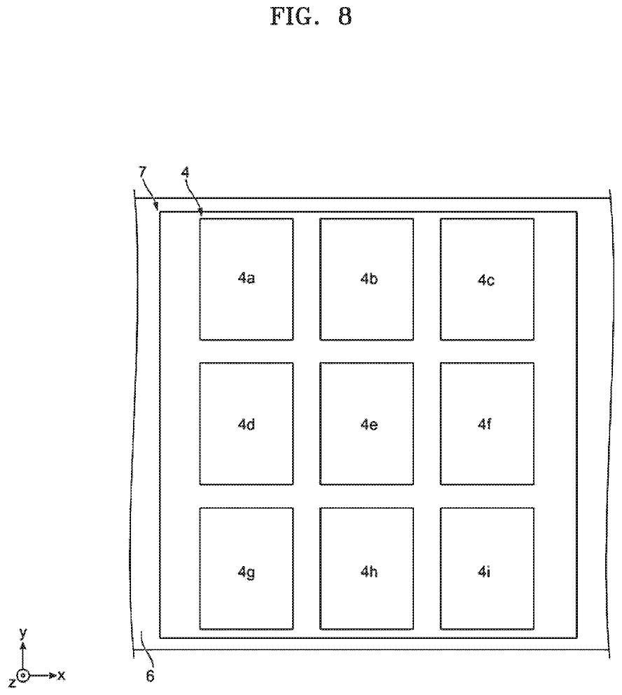

FIG. 8 is a view of a contact sheet 4 and a socket substrate 7 to which Embodiment 2 is applied, as viewed in the z direction.

In the inspection jig head 3 according to an embodiment as illustrated in FIG. 4, a rigid substrate, which is divided into a plurality of socket sections 5a to 5i (see FIG. 4), is used as the socket substrate 5 (see FIG. 1). A configuration of the socket substrate 7 included in an inspection jig head 3 according to one or more other embodiments is different from the configuration of the socket substrate 5 according to the embodiment of FIG. 4.

The socket substrate 7 is a bendable flexible printed circuit (FPC) substrate on which wires for transmitting electrical signals are formed. Also, the socket substrate 7 is not divided into a plurality of sections. Additionally, the socket substrate 7 is formed across a plurality of contact sections 4a to 4i of the contact sheet 4, and the plurality of contact sections 4a to 4i of the contact sheet 4 are stacked on the socket substrate 7.

In the inspection jig head 3 according to one or more other embodiments, the upper surfaces 41 of respective sections of the contact sheet 4, with which the plurality of connection terminals 94 come into contact, move individually in the z direction according to pressing forces exerted by the plurality of connection terminals 94, similar to the embodiments described with respect to FIGS. 1-4. For example, in the inspection jig head 3, respective sections of the contact sheet 4 are deformed individually and elastically according to the pressing forces exerted by the plurality of connection terminals 94. Also, in the inspection jig head 3, the socket substrate 7 is deformed in the z direction according to the pressing forces exerted by the plurality of connection terminals 94. Also, the plurality of probes 61 of the conductive body 6 expand and contract in the z direction according to the deformation of the socket substrate 7, and accordingly, respective sections of the contact sheet 4 are individually moved in the z direction.

Accordingly, even when a warped semiconductor package 9 is mounted on the inspection jig head 3, the plurality of connection terminals 94 come into contact more easily with respective sections of the contact sheet 4 by an appropriate pressing force. As a result, it is difficult for connection failures of the plurality of connection terminals 94 to the contact sheet 4, damage to the plurality of connection terminals 94 due to an increase in a pressing force against the contact sheet 4, or a short circuit in wires to occur.

While embodiments of the disclosure are described above, the disclosure is not limited to the embodiments described above.

In the embodiments described above, respective sections of the contact sheet 4 have the same shape but are not limited thereto. Depending on arrangements of the logic devices 92 and the memory devices 93 of the semiconductor package 9, an arrangement of the plurality of connection terminals 94, etc., shapes and areas of respective sections of the contact sheet 4 viewed in the z direction may be different from each other.

Also, when there is a tendency in the direction of warpage occurring in the semiconductor package 9, thicknesses, durometer hardness, elastic moduli, etc. of respective sections of the contact sheet 4 may be changed according thereto.

For example, when warpage, such as downward convexity in the z direction, is likely to occur in the semiconductor package 9, a section located at the end of the contact sheet 4 may be formed to be thicker than a section located in a central region of the contact sheet 4.

Accordingly, when a warped semiconductor package 9 is mounted on the inspection jig head 3, poor contact between the connection terminal 94 and the section located at the end of the contact sheet 4 is less likely to occur.

When warpage, such as downward convexity in the z direction, is likely to occur in the semiconductor package 9, a durometer hardness of the section located in the central portion of the contact sheet 4 may be lower than a durometer hardness of the section located at the end of the contact sheet 4.

Accordingly, even when the warped semiconductor package 9 is mounted on the inspection jig head 3, the section located in the central portion of the contact sheet 4 is more likely to be elastically deformed when the connection terminal 94 is in contact with the section. As a result, damage to the connection terminal 94 or a short circuit of wires due to an increased pressing force against the contact sheet 4 is less likely to occur.

Also, although in the respective embodiments described above, entirety of the semiconductor package 9 is configured to be connected to the elastic contact sheet 4, embodiments are not limited thereto. In addition to the contact sheet 4, the inspection jig head 3 may include a metal pin head, a non-elastic conductive sheet, etc. In addition, a partial region of the semiconductor package 9 may be connected to a metal pin head, a non-elastic conductive sheet, etc.

Furthermore, although, in the respective embodiments described above, the conductive body 6 includes the plurality of probes 61 that may be expanded and contracted in the z direction and the plurality of probes 61 transmit electrical signals between the test board 2 and the socket substrate 5, embodiments are not limited thereto. The conductive body 6 may also transmit electrical signals between the test board 2 and the socket substrate 5 by using a connector etc. that does not expand and contract in the z direction.

Even when the conductive body 6 transmits an electric signal by using a connector etc. that does not expand and contract in the z direction, problems, such as poor contact between the contact sheet 4 and the connection terminal 94, may be reduced because respective sections of the contact sheet 4 are deformed individually and elastically according to pressing forces exerted by the plurality of connection terminals 94.

According to one or more embodiments, it is possible to prevent poor contact between an inspection target and a contact layer due to warpage of the inspection target from occurring.

Various modifications or combinations may be made as long as the modifications or combinations do not conflict with the idea of the disclosure.

While embodiments have been described with reference to the figures, it will be understood by those of ordinary skill in the art that various changes in form and details may be made therein without departing from the spirit and scope as defined by the following claims and their equivalents.

What is claimed is:

1. An inspection apparatus configured to test characteristics of an inspection target, the inspection apparatus comprising:
a contact layer configured to come into contact with an inspection point of the inspection target;
a socket substrate on the contact layer opposite to the inspection target; and
a conductive body connected to the socket substrate, opposite to the contact layer, the conductive body being connected to the inspection target through the socket substrate and the contact layer,
wherein the contact layer comprises a plurality of contact sections, each contact section of the plurality of contact sections comprises a contact surface configured to contact the inspection point of the inspection target, and the contact surface is configured to move in a first direction.

2. The inspection apparatus of claim 1, wherein the contact layer comprises an elastic sheet, and
wherein a durometer hardness of the socket substrate is greater than a durometer hardness of the contact layer.

3. The inspection apparatus of claim 2, wherein the contact layer comprises an anisotropic conductive sheet.

4. The inspection apparatus of claim 3, wherein the contact layer comprises:
an elastic body comprising a plurality of through-holes penetrating through the elastic body in the first direction; and
a plurality of conductors in the plurality of through-holes, respectively.

5. The inspection apparatus of claim 1, wherein a thickness of the contact layer is 5 μm to 1000 μm.

6. The inspection apparatus of claim 1, wherein the socket substrate comprises:
a first wire connected to the contact layer; and
a second wire connected to the conductive body,
wherein a pitch of the first wire is 5 μm to 200 μm, and
wherein a pitch of the second wire is 200 μm to 3000 μm.

7. The inspection apparatus of claim 6, wherein the conductive body comprises a plurality of probes configured to contact the second wire, and
wherein an interval between the plurality of probes is 200 μm to 3000 μm.

8. The inspection apparatus of claim 1, wherein the socket substrate comprises a plurality of socket sections, and
wherein the plurality of contact sections are on the plurality of socket sections, respectively.

9. The inspection apparatus of claim 1, wherein the socket substrate comprises a foldable flexible printed circuit (FPC) substrate, and
wherein the plurality of contact sections of the contact layer are on the socket substrate.

10. An inspection apparatus configured to test characteristics of an inspection target, the inspection apparatus comprising:
a contact layer configured to contact an inspection point of the inspection target;
a socket substrate on the contact layer opposite to the inspection target; and
a conductive body connected to the socket substrate opposite side to contact layer, the conductive body being configured to be connected to the inspection target through the socket substrate and the contact layer,
wherein the contact layer comprises a plurality of contact sections separated from each other in a horizontal direction, and
wherein each contact section of the plurality of contact sections is configured to move such that an upper surface of each contact section of the plurality of contact sections is inclined relative to a reference plane.

11. The inspection apparatus of claim 10, wherein the conductive body comprises a probe configured to be connected to the socket substrate and extendable and contractable in a vertical direction.

12. The inspection apparatus of claim 10, wherein the reference plane is a lower surface of the conductive body.

13. The inspection apparatus of claim 10, wherein each contact section of the plurality of contact sections is configured to move in a vertical direction.

14. The inspection apparatus of claim 10, wherein the socket substrate comprises a plurality of socket sections separated from each other in the horizontal direction, and
wherein each socket section of the plurality of socket sections is configured to move such that an upper surface of each socket section of the plurality of socket sections is inclined relative to the reference plane.

15. The inspection apparatus of claim 14, wherein each socket section of the plurality of socket sections is configured to move in a vertical direction.

16. The inspection apparatus of claim 10, wherein the contact layer comprises an elastic sheet, and
wherein a durometer hardness of the socket substrate is greater than a durometer hardness of the contact layer.

17. The inspection apparatus of claim 16, wherein the contact layer comprises an anisotropic conductive sheet.

18. The inspection apparatus of claim 10, wherein a thickness of the contact layer is 5 μm to 1000 μm.

19. The inspection apparatus of claim 10, wherein the socket substrate overlaps the plurality of contact sections in a vertical direction.

20. An inspection apparatus configured to test characteristics of an inspection target, the inspection apparatus comprising:
a contact layer configured to contact an inspection point of the inspection target;
a socket substrate on the contact layer opposite to the inspection target; and
a conductive body connected to the socket substrate opposite to the contact layer, the conductive body being configured to be connected to the inspection target through the socket substrate and the contact layer,
wherein the socket substrate comprises a plurality of socket sections separated from each other in a horizontal direction,
wherein the contact layer comprises a plurality of contact sections on an upper surface of each socket section of the plurality of socket sections, and
wherein a durometer hardness of the socket substrate is greater than a durometer hardness of the contact layer.
